(19) United States
(12) Patent Application Publication
(10) Pub. No.: US 2026/0059745 A1
(43) Pub. Date: Feb. 26, 2026

(54) MEMORY DEVICES PROGRAMMED WITH DIELECTRIC STRUCTURES AND METHODS FOR MANUFACTURING THE SAME

(71) Applicant: Taiwan Semiconductor Manufacturing Company, Ltd., Hsinchu (TW)

(72) Inventors: Bo-Wei Wu, Hsinchu City (TW); Chia-En Huang, Hsinchu City (TW); Pin-Dai Sue, Hsinchu City (TW); Jung-Hsuan Chen, Hsinchu City (TW); Ting-Wei Chiang, Hsinchu City (TW)

(73) Assignee: Taiwan Semiconductor Manufacturing Company, Ltd., Hsinchu (TW)

(21) Appl. No.: 18/813,600

(22) Filed: Aug. 23, 2024

(51) Int. Cl. H10B 20/00; H01L 23/522; H01L 23/528

(52) U.S. Cl. CPC H10B 20/367; H01L 23/5226; H01L 23/528; H01L 23/5283; H01L 23/5286

(57) ABSTRACT

A memory device includes a plurality of memory cells, each of the plurality of memory cells configured to store a data bit; a first interconnect structure operatively configured as a bit line and coupled to each of the plurality of memory cells; and a second interconnect structure operatively configured to carry a supply voltage and coupled to each of the plurality of memory cells. The data bit stored by a first one of the plurality of memory cells presents a first logic state when the first memory cell includes a first channel structure, with a first end of the first channel structure connected to a dielectric structure.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a read only memory (ROM) cell, in accordance with some embodiments.

FIG. 2 illustrates a layout for forming a memory array including a plural number of ROM cells, in accordance with some embodiments.

FIG. 3 illustrates a hybrid cross-sectional view of a memory array formed by the layout of FIG. 2, in accordance with some embodiments.

FIG. 4 illustrates a layout for forming a memory array including a plural number of ROM cells, in accordance with some embodiments.

FIG. 5 illustrates a hybrid cross-sectional view of a memory array formed by the layout of FIG. 4, in accordance with some embodiments.

FIG. 6 illustrates a layout for forming a memory array including a plural number of ROM cells, in accordance with some embodiments.

FIG. 7 illustrates a hybrid cross-sectional view of a memory array formed by the layout of FIG. 6, in accordance with some embodiments.

FIG. 8 illustrates a layout for forming a memory array including a plural number of ROM cells, in accordance with some embodiments.

FIG. 9 illustrates a hybrid cross-sectional view of a memory array formed by the layout of FIG. 8, in accordance with some embodiments.

FIG. 10 illustrates a layout for forming a memory array including a plural number of ROM cells, in accordance with some embodiments.

FIG. 11 illustrates a hybrid cross-sectional view of a memory array formed by the layout of FIG. 10, in accordance with some embodiments.

FIG. 12 illustrates a layout for forming a memory array including a plural number of ROM cells, in accordance with some embodiments.

FIG. 13 illustrates a hybrid cross-sectional view of a memory array formed by the layout of FIG. 12, in accordance with some embodiments.

FIG. 14 illustrates a layout for forming a memory array including a plural number of ROM cells, in accordance with some embodiments.

FIG. 15 illustrates a hybrid cross-sectional view of a memory array formed by the layout of FIG. 14, in accordance with some embodiments.

FIG. 16 illustrates a layout for forming a memory array including a plural number of ROM cells, in accordance with some embodiments.

FIG. 17 illustrates a hybrid cross-sectional view of a memory array formed by the layout of FIG. 16, in accordance with some embodiments.

FIG. 18 illustrates a layout for forming a memory array including a plural number of ROM cells, in accordance with some embodiments.

FIG. 19 illustrates a hybrid cross-sectional view of a memory array formed by the layout of FIG. 18, in accordance with some embodiments.

FIG. 20 illustrates a layout for forming a memory array including a plural number of ROM cells, in accordance with some embodiments.

FIG. 21 illustrates a hybrid cross-sectional view of a memory array formed by the layout of FIG. 20, in accordance with some embodiments.

FIG. 22 illustrates a layout for forming a memory array including a plural number of ROM cells, in accordance with some embodiments.

FIG. 23 illustrates a hybrid cross-sectional view of a memory array formed by the layout of FIG. 22, in accordance with some embodiments.

FIG. 24 illustrates a layout for forming a memory array including a plural number of ROM cells, in accordance with some embodiments.

FIG. 25 illustrates a hybrid cross-sectional view of a memory array formed by the layout of FIG. 24, in accordance with some embodiments.

FIG. 26 illustrates a flow chart of a method for forming a memory array programmed with a dielectric structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Read only memory (ROM) arrays are semiconductor memory chip arrays with data permanently stored in the array. ROM arrays are made up of a number of ROM cells, each ROM cell including a transistor in an “on” or “off” state. Each ROM cell is configured to store a (e.g., binary) data bit reflecting that on or off state. To program a ROM cell to an on state or an off state, it generally depends on whether a contact via structure connecting an active region (e.g., a source/drain region) of the transistor to an interconnect structure carrying a ground voltage (e.g., VSS) is formed. Accordingly, a ROM array, which include a plural number of ROM cells, can include a plural number of places where no contact via structures are formed. Such an “uneven” distribution of the contact via structures typically causes manufacturing issues. Thus, the existing ROM devices/arrays have not been entirely satisfactory in certain aspects.

The present disclosure provides various embodiments of a memory device (e.g., a memory array) including a plural number of ROM cells, each of which can be programmed through various front-end-of-line (FEOL) processing techniques. As such, a uniform distribution of contact via structures can be formed across the memory array, which advantageously avoids the above-identified manufacturing issues. For example, after forming a pair of epitaxial structures for each of the ROM cells, one of the epitaxial structures of each of a first group of the ROM cells can be replaced with a dielectric structure while both of the epitaxial structures of each of a second group of the ROM cells can remain. Next, a plural number of contact via structures can be uniformly formed to land on the whole memory array, followed by forming a first interconnect structure configured as a bit line and a second interconnect structure configured as a power rail to carry a ground voltage (e.g., VSS). Such formation of contact via structures and interconnect structures is sometimes referred to as part of back-end-of-line (BEOL) processing. After forming the bit line and the power rail that carries VSS, the ROM cells across the whole array can be readily programmed, e.g., the first group of ROM cells presenting a first logic state and the second group of ROM cells presenting a second logic state.

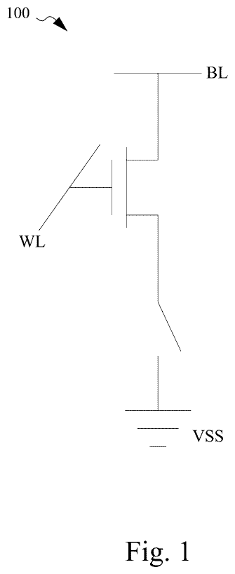

FIG. 1 illustrates an example circuit diagram of a single ROM cell 100, in accordance with some embodiments. A plural number of such ROM cells 100 can be arranged as a (e.g., two-dimensional) array having a plural number of rows and a plural number of columns, each of the ROM cells disposed at an intersection of a corresponding row and a corresponding column. Although the ROM cell 100 shown in FIG. 1 includes one transistor, it should be understood that the circuit diagram of FIG. 1 is provided for illustrative purposes and is not intended to limit the scope of the present disclosure. Accordingly, the ROM cell 100 shown in FIG. 1 can include any of various other components, while remaining within the scope of the present disclosure.

As shown, the ROM cell 100 includes one transistor 110 having a gate terminal, a first source/drain terminal, and a second source/drain terminal. The gate terminal is connected to a word line (WL), the drain terminal is connected to a bit line (BL), and the source terminal is selectively connected to a supply voltage, e.g., a ground voltage (VSS). In some embodiments, whether the ROM cells is in a logical “1” or “0” state can depend on whether the second source/drain terminal of the transistor 110 is connected to the VSS. For example, when the second source/drain terminal is connected to the VSS, the ROM cell 100 presents a logical 1; and when the second source/drain terminal is disconnected from the VSS, the ROM cell 100 presents a logical 0. In some other embodiments (not shown in FIG. 1), whether the ROM cells is in a logical “1” or “0” state can depend on whether the first source/drain terminal of the transistor 110 is connected to the BL. For example, when the first source/drain terminal is connected to the BL, the ROM cell 100 presents a logical 1; and when the first source/drain terminal is disconnected from the BL, the ROM cell 100 presents a logical 0.

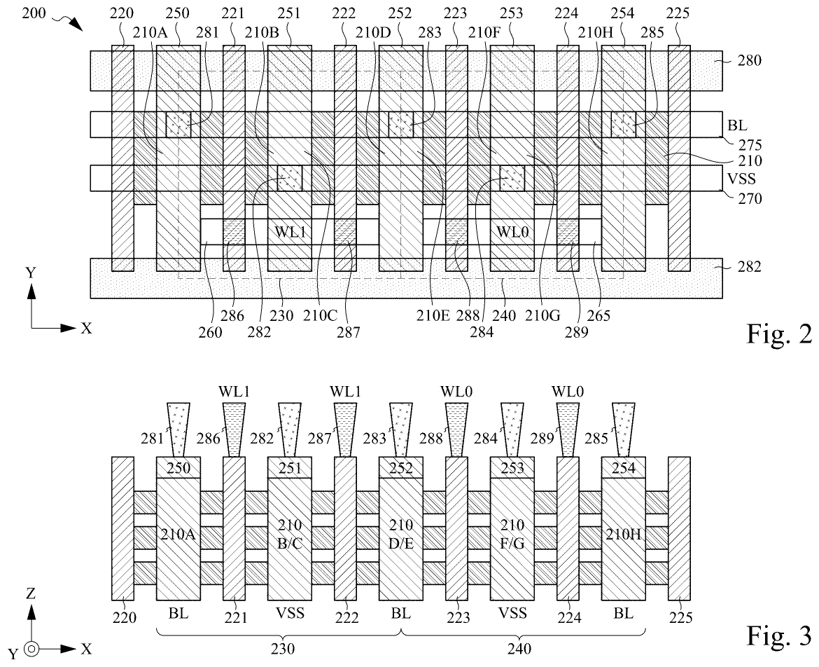

FIG. 2 illustrates an example layout 200 configured to form (or program) a memory array including a first ROM cell and a second ROM cell that both present a logical 1, and FIG. 3 illustrates a hybrid cross-sectional view of the memory array formed by the layout 200 (FIG. 2), in accordance with some embodiments. As disclosed herein, the term “hybrid cross-sectional view” refers to a combination of multiple cross-sectional views overlapped with each other. It should be understood that the layout of FIG. 2 and the corresponding memory array of FIG. 3 are provided merely for illustrative purposes, and are not intended to limit the scope of the present disclosure.

Referring to FIG. 2, the layout 200 includes patterns for forming an active region 210, gate structures 220, 221, 222, 223, 224, and 225, respectively. It should be understood that the layout 200 can include any number of other patterns to form respective active regions or gate structures, while remaining within the scope of present disclosure. In some embodiments, the active region 210 can extend along a first lateral direction (e.g., the X-direction), and the gate structures 220 to 225 can each extend along a second lateral direction (e.g., the Y-direction) perpendicular to the first lateral direction. The gate structures 220 to 225 can each traverse the active region 210. The gate structures 220 to 225 can each correspond to an active (e.g., metal) gate structure. In some embodiments, the active region 210 and the gate structures 220 to 225, formed along the major surface of a substrate, may be referred to as part of front-end-of-line (FEOL) processing.

In some embodiments, the ROM cells of the memory array are each formed as a gate-all-around (GAA) transistor. However, the ROM cells of the memory array (formed by the layout 200) can be formed as any of various other transistor structure while remaining within the scope of the present disclosure. In the example of GAA transistor structures, the active region 210 can be formed of a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by each of the gate structure remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., straddles) the remaining portions of the semiconductor structures can be configured as a gate terminal of the transistor.

In FIG. 2, the active region 210, together with the gate structures 221 and 222, can form a first ROM cell 230 with a two-transistor (2T) configuration. For example, the portion of the active region 210 overlaid by the gate structure 221 may include a number of first nanostructures vertically separated from each other, which can collectively function as the channel of a first sub-transistor, and the portion of the active region 210 overlaid by the gate structure 222 may include a number of second nanostructures vertically separated from each other, which can collectively function as the channel of a second sub-transistor. These two sub-transistors can be coupled to each other in parallel (e.g., respective gate terminals, first source/drain terminals, and second source/drain terminals tied together), thereby forming the first ROM cell 230 in the 2T configuration, in some embodiments.

Further, the portions of the active region 210 that are disposed on opposite sides of each of the gate structures 221 and 222 are replaced with epitaxial structures, respectively. Such epitaxial structures can function as source/drain terminals of the sub-transistors. For example, the gate structure 221 can function as a gate terminal of the first sub-transistor; the gate structure 222 can function as a gate terminal of the second sub-transistor; epitaxial structures (210A and 210B) formed on the opposite sides of the gate structure 221 can function as a first source/drain terminal and second source/drain terminal of the first sub-transistor; epitaxial structures (210C and 210D) formed on the opposite sides of the gate structure 222 can function as a second source/drain terminal and first source/drain terminal of the second sub-transistor. The second source/drain terminal (e.g., 210B) of the first sub-transistor and the second source/drain terminal (e.g., 210C) of the second sub-transistor are connected to (merged with) each other.

Similarly, the active region 210, together with the gate structures 223 and 224, can form a second ROM cell 240 in the same 2T configuration, e.g., with two sub-transistors coupled to each other in parallel. A first one of the two sub-transistors is formed by the gate structure 224, and epitaxial structures 210H and 210G that serve as its first and second source/drain terminals, respectively. A second one of the two sub-transistor is formed by the gate structure 223, and epitaxial structures 210E and 210F that serve as its first and second source/drain terminals, respectively. The second source/drain terminal (e.g., 210F) of the second sub-transistor and the second source/drain terminal (e.g., 210G) of the first sub-transistor are connected to (merged with) each other. As such, it should be appreciated that the respective components of the first ROM cell 230 and the second ROM cell 240 are symmetrical to each other with respect to a virtual axis interposed between the gate structures 222 and 223.

Still referring to FIG. 2, the layout 200 further includes patterns for forming source/drain contact structures (each sometimes referred to as MD) 250, 251, 252, 253, and 254, interconnect structures 260, 265, 270, and 275, respectively. It should be understood that the layout 200 can include any number of other patterns to form respective MDs or interconnect structures, while remaining within the scope of present disclosure. In some embodiments, the MDs 250 to 254 can each extend along the second lateral direction (e.g., the Y-direction), and the interconnect structures 260 to 275 can each extend along the first lateral direction (e.g., the X-direction). The MDs 250 to 254 can each be in electrical contact with a corresponding epitaxial structure (the source/drain terminal of a transistor or sub-transistor). The interconnect structures 260 to 275 can each be electrically coupled to one or more corresponding gate structures or one or more corresponding MDs.

For example, the interconnect structure 260 coupled to the gate structures 221 and 222 may serve as a first word line (WL1) of the memory array; the interconnect structure 270 coupled to the MDs 251 and 253 may serve as a power rail carrying the VSS (hereinafter “VSS”) for the memory array; and the interconnect structure 275 coupled to the MDs 250, 252, and 254 may serve as a bit line (BL) of the memory array. In some embodiments, the MDs 250 to 254, formed right above the active region and gate structure (e.g., FEOL), may be referred to as part of middle-end-of-line (MEOL) processing, and the interconnect structures 260 to 275, formed in metallization layers above the active region and gate structure, may be referred to as part of back-end-of-line (BEOL) processing.

The layout 200 further includes patterns for forming a plural number of via structures 281, 282, 283, 284, 285, 286, 287, 288, and 289, respectively. For example, the via structure 281 can couple the MD 250 (which is electrically coupled to the first source/drain terminal of the first sub-transistor of the ROM cell 230) to the interconnect structure 275 (BL); the via structure 282 can couple the MD 251 (which is electrically coupled to the second source/drain terminals of the first and second sub-transistors of the ROM cell 230) to the interconnect structure 270 (VSS); the via structure 283 can couple the MD 252 (which is electrically coupled to the first source/drain terminal of the second sub-transistor of the ROM cell 230 and to the first source/drain terminal of the first sub-transistor of the ROM cell 240) to the interconnect structure 275 (BL); the via structures 286 and 287 can respectively couple the gate structures 221 and 222 (which are respective gate terminals of the first and second sub-transistors of the ROM cell 230) to the interconnect structure 260 (WL1); the via structure 284 can couple the MD 253 (which is electrically coupled to the second source/drain terminals of the first and second sub-transistors of the ROM cell 240) to the interconnect structure 270 (VSS); the via structure 285 can couple the MD 254 (which is electrically coupled to the first source/drain terminal of the second sub-transistor of the ROM cell 240) to the interconnect structure 275 (BL); the via structures 288 and 289 can respectively couple the gate structures 223 and 224 (which are respective gate terminals of the first and second sub-transistors of the ROM cell 240) to the interconnect structure 265 (WL0).

Based on the layout 200 of FIG. 2, a memory array including at least a first ROM cell (e.g., 230) and a second ROM cell (e.g., 240) can be formed. The first ROM cell 230 can be formed based on two sub-transistors coupled to each other in parallel. For example, the first sub-transistor of the first ROM cell 230 includes its gate terminal, first source/drain terminal, and second source/drain terminal formed by the gate structure 221, the epitaxial structure 210A, and the epitaxial structure 210B, respectively; and the second sub-transistor of the first ROM cell 230 includes its gate terminal, first source/drain terminal, and second source/drain terminal formed by the gate structure 222, the epitaxial structure 210C, and the epitaxial structure 210D. Similarly, the second ROM cell 240 can be formed based on two sub-transistors coupled to each other in parallel. For example, the first sub-transistor of the second ROM cell 240 includes its gate terminal, first source/drain terminal, and second source/drain terminal formed by the gate structure 224, the epitaxial structure 210H, and the epitaxial structure 210G, respectively; and the second sub-transistor of the second ROM cell 240 includes its gate terminal, first source/drain terminal, and second source/drain terminal formed by the gate structure 223, the epitaxial structure 210E, and the epitaxial structure 210F.

Further, the first source/drain terminals of the first and second sub-transistors of the first ROM cell 230, which serve as a drain terminal of the first ROM cell 230, and the first source/drain terminals of the first and second sub-transistors of the second ROM cell 240, which serve as a drain terminal of the second ROM cell 240, are electrically coupled to the interconnect structure 275 that serves as the BL, through respective MDs (e.g., 250, 252, 254) and via structures (e.g., 281, 283, 285). The second source/drain terminals of the first and second sub-transistors of the first ROM cell 230, which serve as a source terminal of the first ROM cell 230, and the second source/drain terminals of the first and second sub-transistors of the second ROM cell 240, which serve as a source terminal of the second ROM cell 240, are electrically coupled to the interconnect structure 270 that serves as the VSS, through respective MDs (e.g., 251, 253) and via structures (e.g., 282, 284). The gate terminals of the first and second sub-transistors of the first ROM cell 230, which serve as a gate terminal of the first ROM cell 230, are electrically coupled to the interconnect structure 260 that serves as the WL1. The gate terminals of the first and second sub-transistors of the second ROM cell 240, which serve as a gate terminal of the second ROM cell 240, are electrically coupled to the interconnect structure 265 that serves as the WL0.

The hybrid cross-sectional view of FIG. 3 illustrates a combination of cross-sectional views of the memory array formed based on the layout 200 (FIG. 2). For example, a first cross-sectional view can be cut along the interconnect structure 275 (BL), which shows at least the epitaxial structures 210A to 210H, the MDs 250 to 254 disposed thereupon, and the via structures 281, 283, and 285; a second cross-sectional view can be cut along the interconnect structure 270 (VSS), which shows at least the epitaxial structures 210A to 210H, the MDs 250 to 254 disposed thereupon, and the via structures 282 and 284; and a third cross-sectional view can be cut along the interconnect structures 260 and 265 (WL1, WL0), which shows the gate structures 221 to 224, the via structures 286 to 289 disposed thereupon, and the MDs 250 to 254.

As shown in FIG. 3, the first ROM cell 230 can have its source terminal (formed by the merged epitaxial structures 210B and 210C) electrically coupled to the VSS through the MD 251 and via structure 282, its drain terminal (formed by the separate epitaxial structures 210A and 210D) electrically coupled to the BL through the MDs 250 and 252 and via structures 281 and 283, and its gate terminal (formed by the gate structures 221 and 222) electrically coupled to the WL1 through the via structures 286 and 287. The second ROM cell 240 can have its source terminal (formed by the merged epitaxial structures 210F and 210F) electrically coupled to the VSS through the MD 253 and via structure 284, its drain terminal (formed by the separate epitaxial structures 210E and 210H) electrically coupled to the BL through the MDs 252 and 254 and via structures 283 and 285, and its gate terminal (formed by the gate structures 223 and 224) electrically coupled to the WL0 through via structures 288 and 289. Accordingly, the first ROM cell 230 and the second ROM cell 240 can both present (or be programmed/coded with) a logical 1, in accordance with various embodiments of the present disclosure.

Referring again to FIG. 2, the layout 200 can further include patterns for forming a first cut structure 280 and a second cut structure 282, respectively. As shown, the cut structures 280 and 282 are in parallel with each other and extend along the first lateral direction (e.g., the X-direction). In some embodiments, the cut structures 280 and 282 can each traverse across the gate structures 220 to 225 to separate each of the gate structures 220 to 225 into multiple sections (separated apart from one another along the Y-direction). For example, the cut structure 280 can separate each of the gate structures 220 to 225 shown in FIG. 2 from its respective section disposed above the ROM cells 230-240 along the Y-direction (not shown); and the cut structure 282 can separate each of the gate structures 220 to 225 shown in FIG. 2 from its respective section disposed below the ROM cells 230-240 along the Y-direction (not shown).

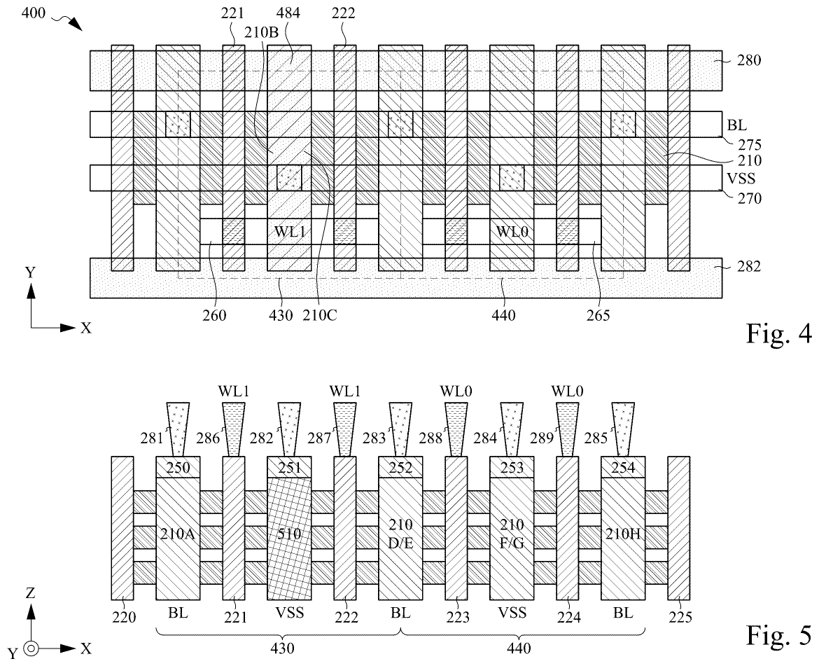

FIG. 4 illustrates an example layout 400 configured to form (or program) a memory array including a first ROM cell (e.g., 430) and a second ROM cell (e.g., 440) that present a logical 0 and a logical 1, respectively, and FIG. 5 illustrates a hybrid cross-sectional view of the memory array formed by the layout 400 (FIG. 4), in accordance with some embodiments. It should be understood that the layout of FIG. 4 and the corresponding memory array of FIG. 5 are provided merely for illustrative purposes, and are not intended to limit the scope of the present disclosure.

The layout 400 is substantially similar to the layout 200 (FIG. 2), except that the layout 400 further includes a pattern for forming another cut structure 484 extending along a direction perpendicular to the cut structures 280 and 282. In some embodiments, the cut structure 484, together with at least one of the cut structure 280 or 282, can sometimes be referred to as a cut structure having a T-shape. Accordingly, the reference numerals of other features similar in the layout 200 (FIG. 2) are reused in the following discussion of FIG. 4.

In some embodiments of the present disclosure, the cut structure 484 can overlap the epitaxial structures 210B and 210C. As a result, after forming the epitaxial structures 210B and 210C (and other epitaxial structures in the active region 210), the cut structure 484 can be used to remove the epitaxial structures 210B and 210C to form a vertical trench that can expose respective sidewalls of the nanostructures that are respectively overlaid by the gate structures 221 and 222 and expose the major surface of the substrate, and the vertical trench can later be filled with a dielectric material to form a dielectric structure (e.g., 510 shown in FIG. 5). The dielectric material of the dielectric structure 510 can include silicon oxide, silicon nitride, or combinations thereof.

After filling up the vertical trench, the dielectric structure 510 can be in physical contact with the exposed sidewalls of the nanostructures that are respectively overlaid by the gate structures 221 and 222, and in physical contact with the substrate. In some embodiments, the nanostructures overlaid by the gate structure 221 operatively serve as the channel of the first sub-transistor of the first ROM cell 430, and the nanostructures overlaid by the gate structure 222 operatively serve as the channel of the second sub-transistor of the first ROM cell 430. Next, the MDs 250 to 254 remain formed on top of the remaining epitaxial structures 210A, the dielectric structure 510, and the remaining epitaxial structures 210D-H, respectively. As shown in FIG. 5, the MD 251 is in physical contact with but electrically isolated from the dielectric structure 510. Next, the via structures 281 to 289 can be evenly formed over the whole array, followed by the formation of the interconnect structures 260, 265, 270, and 275 that serve as the WL1, WL0, VSS, and BL, respectively.

Alternatively stated, the interconnect structure 275 (VSS) can be physically coupled to but electrically isolated from the dielectric structure 510. The first ROM cell 430 can have its drain terminal electrically connected to the BL and its source terminal electrically disconnected from VSS, while the second ROM cell 440 can still have its drain and source terminals electrically connected to the BL and VSS, respectively. Accordingly, the first ROM cell 430 and the second ROM cell 440 can present (or be programmed/coded with) a logical 0 and a logical 1, respectively, in accordance with various embodiments of the present disclosure.

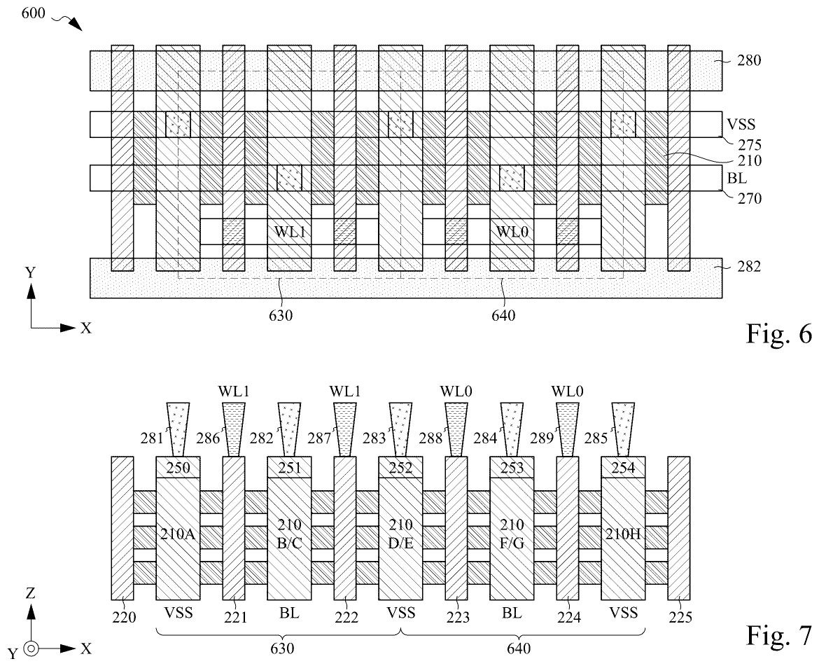

FIG. 6 illustrates an example layout 600 configured to form (or program) a memory array including a first ROM cell (e.g., 630) and a second ROM cell (e.g., 640) that both present a logical 1, and FIG. 7 illustrates a hybrid cross-sectional view of the memory array formed by the layout 600 (FIG. 6), in accordance with some embodiments. It should be understood that the layout of FIG. 6 and the corresponding memory array of FIG. 7 are provided merely for illustrative purposes, and are not intended to limit the scope of the present disclosure.

As shown, the layout 600 is substantially similar to the layout 200 (FIG. 2), except that interconnect structures 270 and 275 of the layout 600 are configured as the BL and VSS, respectively. Accordingly, the reference numerals of other features similar in the layout 200 (FIG. 2) are reused in the following discussion of FIG. 6.

By configuring the interconnect structure 270 as the BL and the interconnect structure 275 as the VSS, the epitaxial structure 210A is electrically coupled to the VSS through the corresponding MD and via structure, the epitaxial structures 210B-C are electrically coupled to the BL through the corresponding MD and via structure, the epitaxial structures 210D-E are electrically coupled to the VSS through the corresponding MD and via structure, the epitaxial structures 210F-G are electrically coupled to the BL through the corresponding MD and via structure, and the epitaxial structure 210H is electrically coupled to the VSS through the corresponding MD and via structure, as illustrated in the hybrid cross-sectional view of FIG. 7. Accordingly, the first ROM cell 630 and the second ROM cell 640 can both present (or be programmed/coded with) a logical 1, in accordance with various embodiments of the present disclosure.

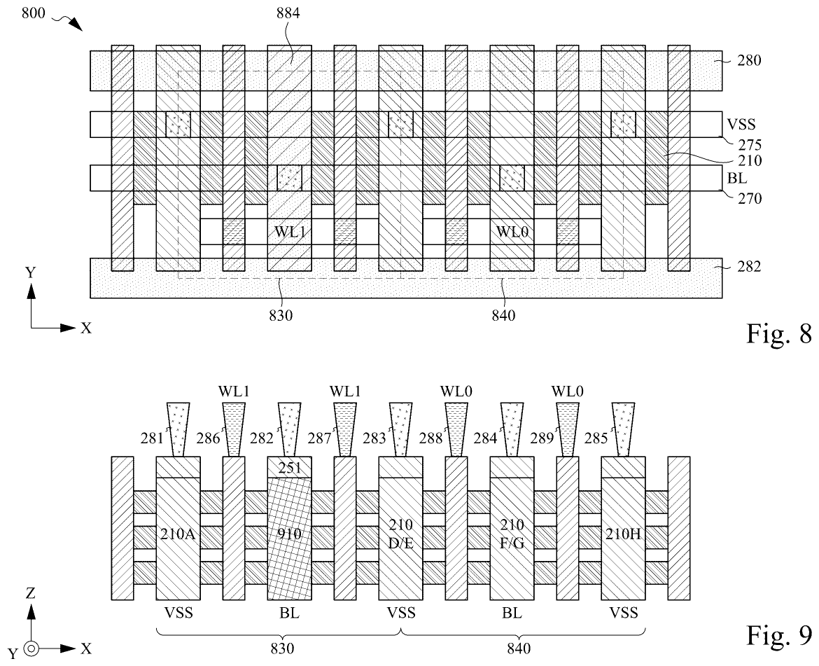

FIG. 8 illustrates an example layout 800 configured to form (or program) a memory array including a first ROM cell (e.g., 830) and a second ROM cell (e.g., 840) that present a logical 0 and a logical 1, respectively, and FIG. 9 illustrates a hybrid cross-sectional view of the memory array formed by the layout 800 (FIG. 8), in accordance with some embodiments. It should be understood that the layout of FIG. 8 and the corresponding memory array of FIG. 9 are provided merely for illustrative purposes, and are not intended to limit the scope of the present disclosure.

As shown in FIG. 8, the layout 800 is substantially similar to the layout 600 (FIG. 6), except that the layout 800 further includes a pattern for forming another cut structure 884 extending along a direction perpendicular to the cut structures 280 and 282. In some embodiments, the cut structure 884, together with at least one of the cut structure 280 or 282, can sometimes be referred to as a cut structure having a T-shape. Accordingly, the reference numerals of other features similar in the layout 600 (FIG. 6) are reused in the following discussion of FIG. 8.

In some embodiments, the cut structure 884 can overlap the epitaxial structures 210B and 210C. As a result, after forming the epitaxial structures 210B and 210C (and other epitaxial structures in the active region 210), the cut structure 884 can be used to remove the epitaxial structures 210B and 210C to form a vertical trench that can expose respective sidewalls of the nanostructures that are respectively overlaid by the gate structures 221 and 222 and expose the major surface of the substrate, and the vertical trench can later be filled with a dielectric material to form a dielectric structure (e.g., 910 shown in FIG. 9). The dielectric material of the dielectric structure 910 can include silicon oxide, silicon nitride, or combinations thereof.

After filling up the vertical trench, the dielectric structure 910 can be in physical contact with the exposed sidewalls of the nanostructures that are respectively overlaid by the gate structures 221 and 222, and in physical contact with the substrate. In some embodiments, the nanostructures overlaid by the gate structure 221 operatively serve as the channel of the first sub-transistor of the first ROM cell 830, and the nanostructures overlaid by the gate structure 222 operatively serve as the channel of the second sub-transistor of the first ROM cell 830. Next, the MDs 250 to 254 remain formed on top of the remaining epitaxial structures 210A, the dielectric structure 910, and the remaining epitaxial structures 210D-H, respectively. As shown in FIG. 9, the MD 251 is in physical contact with but electrically isolated from the dielectric structure 910. Next, the via structures 281 to 289 can be evenly formed over the whole array, followed by the formation of the interconnect structures 260, 265, 270, and 275 that serve as the WL1, WL0, BL, and VSS, respectively.

Alternatively stated, the interconnect structure 270 (BL) can be physically coupled to but electrically isolated from the dielectric structure 910. The first ROM cell 830 can have its source terminal electrically connected to the VSS and its drain terminal electrically disconnected from the BL, while the second ROM cell 840 can still have its drain and source terminals electrically connected to the BL and VSS, respectively. Accordingly, the first ROM cell 830 and the second ROM cell 840 can present (or be programmed/coded with) a logical 0 and a logical 1, respectively, in accordance with various embodiments of the present disclosure.

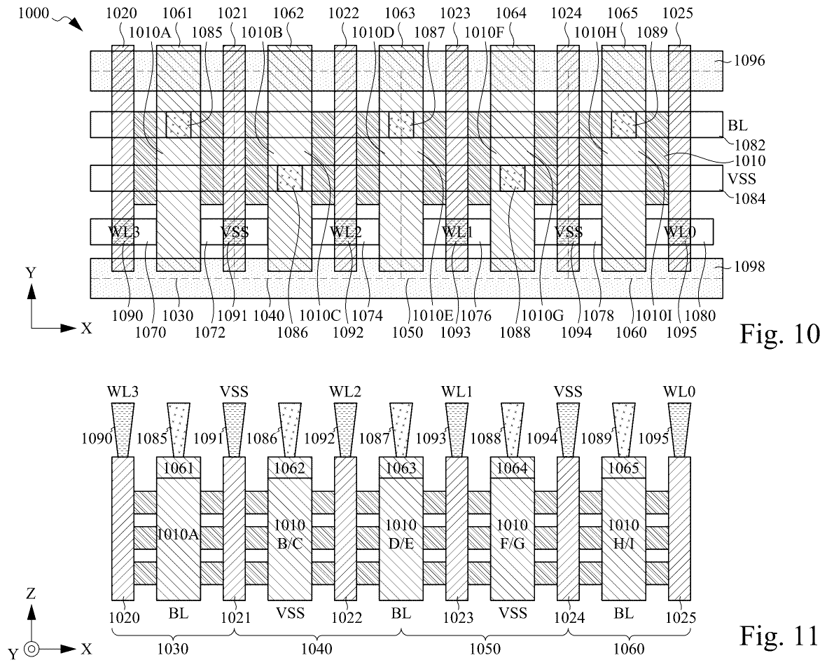

FIG. 10 illustrates an example layout 1000 configured to form (or program) a memory array including a first ROM cell, a second ROM cell, a third ROM cell, and a fourth ROM cell that all present a logical 1, and FIG. 11 illustrates a hybrid cross-sectional view of the memory array formed by the layout 1000 (FIG. 10), in accordance with some embodiments. It should be understood that the layout of FIG. 10 and the corresponding memory array of FIG. 11 are provided merely for illustrative purposes, and are not intended to limit the scope of the present disclosure.

Referring to FIG. 10, the layout 1000 includes patterns for forming an active region 1010, gate structures 1020, 1021, 1022, 1023, 1024, and 1025, respectively. It should be understood that the layout 1000 can include any number of other patterns to form respective active regions or gate structures, while remaining within the scope of present disclosure. In some embodiments, the active region 1010 can extend along a first lateral direction (e.g., the X-direction), and the gate structures 1020 to 1025 can each extend along a second lateral direction (e.g., the Y-direction) perpendicular to the first lateral direction. The gate structures 1020 to 1025 can each traverse the active region 1010. The gate structures 1020 to 1025 can each correspond to an active (e.g., metal) gate structure.

In some embodiments, the ROM cells of the memory array are each formed as a gate-all-around (GAA) transistor. However, the ROM cells of the memory array (formed by the layout 1000) can be formed as any of various other transistor structure while remaining within the scope of the present disclosure. In the example of GAA transistor structures, the active region 1010 can be formed of a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by each of the gate structure remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., straddles) the remaining portions of the semiconductor structures can be configured as a gate terminal of the transistor.

In FIG. 10, the active region 1010, together with the gate structures 1021 and 1022, can form a first ROM cell 1040 with a one and half-transistor (1.5T) configuration. For example, the portion of the active region 1010 overlaid by the gate structure 1021 may include a number of first nanostructures vertically separated from each other, which can collectively function as the channel of a first sub-transistor, and the portion of the active region 1010 overlaid by the gate structure 1022 may include a number of second nanostructures vertically separated from each other, which can collectively function as the channel of a second sub-transistor. In some embodiments, the gate terminal (e.g., 1021) of the first sub-transistor can be tied to VSS, causing the first sub-transistor to remain turned-off, while the gate terminal (e.g., 1022) of the second sub-transistor can be coupled to a corresponding word line (WL). Accordingly, the first ROM cell 1040 with a 1.5T configuration can be formed.

Further, the portions of the active region 1010 that are disposed on opposite sides of each of the gate structures 1021 and 1022 are replaced with epitaxial structures, respectively. Such epitaxial structures can function as source/drain terminals of the sub-transistors. For example, the gate structure 1022 can function as a gate terminal of the second sub-transistor, while the gate structure 1021, tied to the VSS, can function as a gate terminal of the inactive (or turned-off) first sub-transistor. Epitaxial structures (1010D and 1010C) formed on the opposite sides of the gate structure 1022 can function as a first source/drain terminal and second source/drain terminal of the second sub-transistor, while epitaxial structure (1010B) formed on one side of the gate structure 1021 can function as one of the source/drain terminals of the inactive first sub-transistor. Similarly, the active region 1010, together with the gate structure 1023 and gate structure 1024 tied to the VSS, can form a second ROM cell 1050 in the same 1.5T configuration; the active region 1010, together with the gate structure 1020 and the gate structure 1021 tied to the VSS, can form a third ROM cell 1030 in the same 1.5T configuration; and the active region 1010, together with the gate structure 1025 and the gate structure 1024 tied to the VSS, can form a fourth ROM cell 1060 in the same 1.5T configuration.

Still referring to FIG. 10, the layout 1000 further includes patterns for forming source/drain contact structures (each sometimes referred to as MD) 1061, 1062, 1063, 1064, and 1065, interconnect structures 1070, 1072, 1074, 1076, 1078, 1080, 1082, and 1084, respectively. It should be understood that the layout 1000 can include any number of other patterns to form respective MDs or interconnect structures, while remaining within the scope of present disclosure. In some embodiments, the MDs 1061 to 1065 can each extend along the second lateral direction (e.g., the Y-direction), and the interconnect structures 1070 to 1084 can each extend along the first lateral direction (e.g., the X-direction). The MDs 1061 to 1065 can each be in electrical contact with a corresponding epitaxial structure (the source/drain terminal of a transistor or sub-transistor). The interconnect structures 1070 to 1084 can each be electrically coupled to one or more corresponding gate structures or one or more corresponding MDs.

For example, the interconnect structure 1074 coupled to the gate structure 1022 may serve as a first word line (WL2) of the memory array; the interconnect structure 1076 coupled to the gate structure 1023 may serve as a second word line (WL1) of the memory array; the interconnect structure 1070 coupled to the gate structure 1020 may serve as a third word line (WL3) of the memory array; the interconnect structure 1080 coupled to the gate structure 1025 may serve as a fourth word line (WL0) of the memory array; the interconnect structure 1084 coupled to the MDs 1062 and 1064 may serve as a power rail carrying the VSS (hereinafter “VSS”) for the memory array; and the interconnect structure 1082 coupled to the MDs 1061, 1063, and 1065 may serve as a bit line (BL) of the memory array.

The layout 1000 further includes patterns for forming a plural number of via structures 1085, 1086, 1087, 1088, 1089, 1090, 1091, 1092, 1093, 1094, and 1095, respectively. For example, the via structure 1085 can couple the MD 1061 (which is electrically coupled to one of the source/drain terminals of the ROM cell 1030) to the interconnect structure 1082 (BL); the via structure 1090 can couple the gate structure 1020 (which is the gate terminal of the ROM cell 1030) to the interconnect structure 1070 (WL3); the via structure 1091 can couple the gate structure 1021 to the interconnect structure 1072 (which is tied to VSS); the via structure 1086 can couple the MD 1062 (which is electrically coupled to one of the source/drain terminals of the ROM cell 1040) to the interconnect structure 1084 (VSS); the via structure 1087 can couple the MD 1063 (which is electrically coupled to one of the source/drain terminals of the ROM cell 1040) to the interconnect structure 1082 (BL); and the via structure 1092 can couple the gate structure 1022 (which is the gate terminal of the ROM cell 1040) to the interconnect structure 1074 (WL2).

Based on the layout 1000 of FIG. 10, a memory array including at least a first ROM cell (e.g., 1040), a second ROM cell (e.g., 1050), a third ROM cell (e.g., 1030), and a fourth ROM cell (e.g., 1060) can be formed. For example, the first ROM cell 1040 includes its gate terminal, first source/drain terminal, and second source/drain terminal formed by the gate structure 1022, the epitaxial structure 1010D, and the epitaxial structure 1010C, respectively. Further, the first source/drain terminal of the first ROM cell 1040, which serve as a drain terminal of the first ROM cell 1040, and the second source/drain terminal of the first ROM cell 1040, which serve as a source terminal of the first ROM cell 1040, are electrically coupled to the interconnect structure 1082 that serves as the BL and the interconnect structure 1084 that serves as the VSS, respectively. The second ROM cell 1050 includes its gate terminal, first source/drain terminal, and second source/drain terminal formed by the gate structure 1023, the epitaxial structure 1010E, and the epitaxial structure 1010F, respectively. Further, the first source/drain terminal of the first ROM cell 1050, which serve as a drain terminal of the second ROM cell 1050, and the second source/drain terminal of the second ROM cell 1050, which serve as a source terminal of the second ROM cell 1050, are electrically coupled to the interconnect structure 1082 that serves as the BL and the interconnect structure 1084 that serves as the VSS, respectively.

The hybrid cross-sectional view of FIG. 11 illustrates a combination of cross-sectional views of the memory array formed based on the layout 1000 (FIG. 10). For example, a first cross-sectional view can be cut along the interconnect structure 1082 (BL), which shows at least the epitaxial structures 1010A to 1010I, the MDs 1061 to 1065 disposed thereupon, and the via structures 1085, 1087, and 1089; a second cross-sectional view can be cut along the interconnect structure 1084 (VSS), which shows at least the epitaxial structures 1010A to 1010I, the MDs 1061 to 1065 disposed thereupon, and the via structures 1086 and 1088; and a third cross-sectional view can be cut along the interconnect structures 1070 to 1080 (WL3, VSS, WL2, WL1, VSS, WL0), which shows the gate structures 1020 to 1025, the via structures 1090 to 1095 disposed thereupon, and the MDs 1061 to 1065.

As shown in FIG. 11, the first ROM cell 1040 can have its source terminal (formed by the merged epitaxial structures 1010B and 1010C) electrically coupled to the VSS through the MD 1062 and via structure 1086, its drain terminal (formed by the merged epitaxial structures 1010D and 1010E) electrically coupled to the BL through the MD 1063 and via structure 1087, and its gate terminal (formed by the gate structure 1022) electrically coupled to the WL2 through the via structure 1092. The second ROM cell 1050 can have its source terminal (formed by the merged epitaxial structures 1010F and 1010G) electrically coupled to the VSS through the MD 1064 and via structure 1088, its drain terminal (formed by the merged epitaxial structures 1010D and 1010E) electrically coupled to the BL through the MD 1063 and via structure 1087, and its gate terminal (formed by the gate structure 1023) electrically coupled to the WL1 through the via structure 1093. The third ROM cell 1030 and the fourth ROM cell 1060 can have their respective gate terminals, drain terminals, and source terminals with similar electrical connection, and thus, the description is not repeated. Accordingly, the ROM cell 1030 to 1060 can all present (or be programmed/coded with) a logical 1, in accordance with various embodiments of the present disclosure.

Referring again to FIG. 10, the layout 1000 can further include patterns for forming a first cut structure 1096 and a second cut structure 1098, respectively. As shown, the cut structures 1096 and 1098 are in parallel with each other and extend along the first lateral direction (e.g., the X-direction). In some embodiments, the cut structures 1096 and 1098 can each traverse across the gate structures 1020 to 1025 to separate each of the gate structures 1020 to 1025 into multiple sections (separated apart from one another along the Y-direction). For example, the cut structure 1096 can separate each of the gate structures 1020 to 1025 shown in FIG. 10 from its respective section disposed above the ROM cells 1030-1060 along the Y-direction (not shown); and the cut structure 1098 can separate each of the gate structures 1020 to 1025 shown in FIG. 10 from its respective section disposed below the ROM cells 1030-1060 along the Y-direction (not shown).

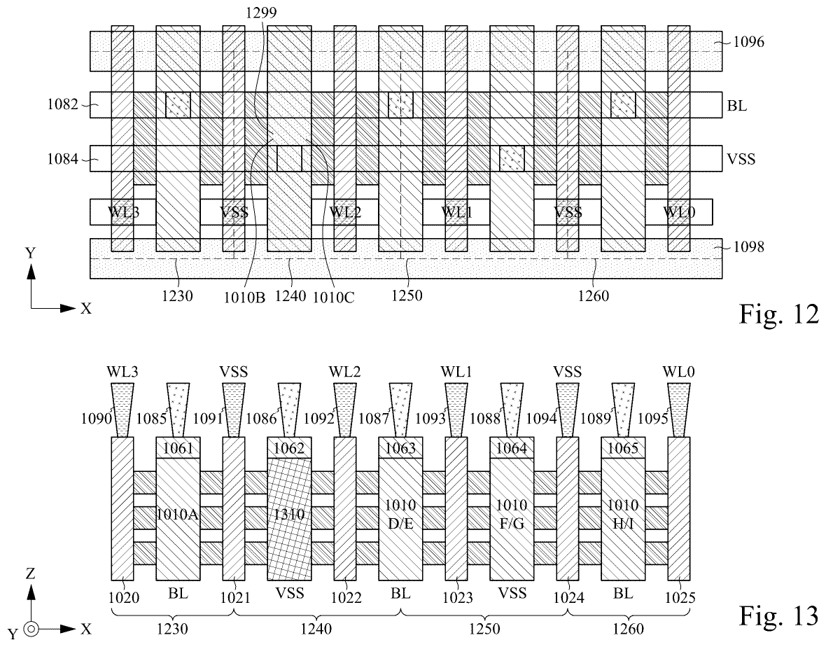

FIG. 12 illustrates an example layout 1200 configured to form (or program) a memory array including a first ROM cell (e.g., 1240), a second ROM cell (e.g., 1250), a third ROM cell (e.g., 1230), and a fourth ROM cell (e.g., 1260) that present a logical 0, a logical 1, a logical 1, and a logical 1, respectively, and FIG. 13 illustrates a hybrid cross-sectional view of the memory array formed by the layout 1200 (FIG. 12), in accordance with some embodiments. It should be understood that the layout of FIG. 12 and the corresponding memory array of FIG. 13 are provided merely for illustrative purposes, and are not intended to limit the scope of the present disclosure.

The layout 1200 is substantially similar to the layout 1000 (FIG. 10), except that the layout 1200 further includes a pattern for forming another cut structure 1299 extending along a direction perpendicular to the cut structures 1096 and 1098. In some embodiments, the cut structure 1299, together with at least one of the cut structure 1096 or 1098, can sometimes be referred to as a cut structure having a T-shape. Accordingly, the reference numerals of other features similar in the layout 1000 (FIG. 10) are reused in the following discussion of FIG. 12.

In some embodiments of the present disclosure, the cut structure 1299 can overlap the epitaxial structures 1010B and 1010C. As a result, after forming the epitaxial structures 1010B and 1010C (and other epitaxial structures in the active region 1010), the cut structure 1299 can be used to remove the epitaxial structures 1010B and 1010C to form a vertical trench that can expose respective sidewalls of the nanostructures that are respectively overlaid by the gate structures 1021 and 1022 and expose the major surface of the substrate, and the vertical trench can later be filled with a dielectric material to form a dielectric structure (e.g., 1310 shown in FIG. 13). The dielectric material of the dielectric structure 1310 can include silicon oxide, silicon nitride, or combinations thereof.

After filling up the vertical trench, the dielectric structure 1310 can be in physical contact with the exposed sidewalls of the nanostructures that are respectively overlaid by the gate structures 1021 and 1022, and in physical contact with the substrate. In some embodiments, the nanostructures overlaid by the gate structure 1021 operatively serve as the channel of the inactive first sub-transistor of the first ROM cell 1040, and the nanostructures overlaid by the gate structure 1022 operatively serve as the channel of the second sub-transistor of the first ROM cell 1040. Next, the MDs 1061 to 1065 remain formed on top of the remaining epitaxial structures 1010A, the dielectric structure 1310, and 1010D-I, respectively. As shown in FIG. 13, the MD 1062 is in physical contact with but electrically isolated from the dielectric structure 1310. Next, the via structures 1085 to 1095 can be evenly formed over the whole array, followed by the formation of the interconnect structures 1082, 1084, 1070, 1072, 1074, 1076, 1078, and 1080 that serve as the BL, VSS, WL3, VSS, WL2, WL1, VSS, and WL0, respectively.

Alternatively stated, the interconnect structure 1084 (VSS) can be physically coupled to but electrically isolated from the dielectric structure 1310. The first ROM cell 1040 can have its drain terminal electrically connected to the BL and its source terminal electrically disconnected from VSS, while each of the other ROM cells 1030, 1050, and 1060 can still have its drain and source terminals electrically connected to the BL and VSS, respectively. Accordingly, the first ROM cell 1040, the second ROM cell 1050, the third ROM cell 1030, and the fourth ROM cell 1060 can present (or be programmed/coded with) a logical 0, a logical 1, a logical 1, and a logical 1, respectively, in accordance with various embodiments of the present disclosure.

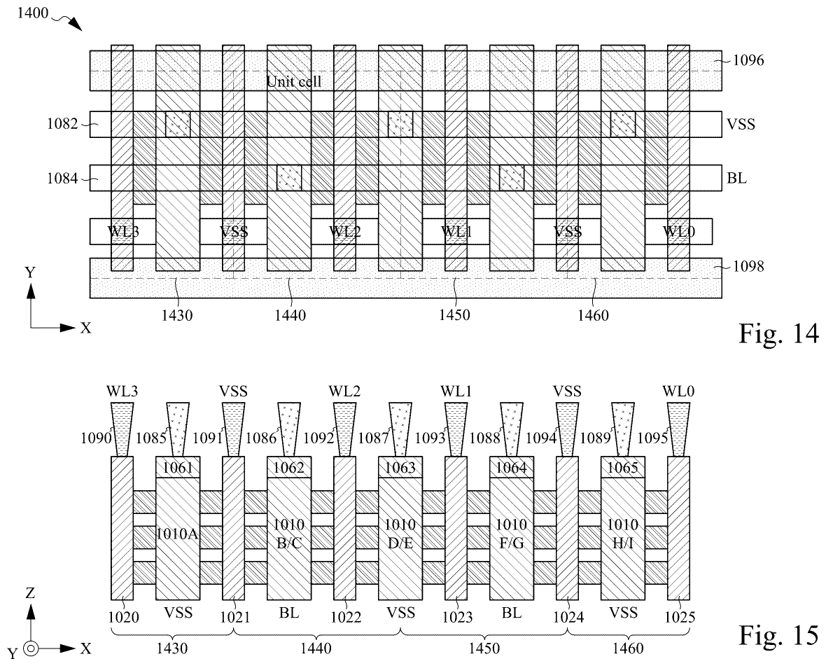

FIG. 14 illustrates an example layout 1400 configured to form (or program) a memory array including a first ROM cell (e.g., 1440), a second ROM cell (e.g., 1450), a third ROM cell (e.g., 1430), and a fourth ROM cell (e.g., 1460) that all present a logical 1, and FIG. 15 illustrates a hybrid cross-sectional view of the memory array formed by the layout 1400 (FIG. 14), in accordance with some embodiments. It should be understood that the layout of FIG. 14 and the corresponding memory array of FIG. 15 are provided merely for illustrative purposes, and are not intended to limit the scope of the present disclosure.

As shown, the layout 1400 is substantially similar to the layout 1000 (FIG. 10), except that interconnect structures 1082 and 1084 of the layout 1400 are configured as the VSS and BL, respectively. Accordingly, the reference numerals of other features similar in the layout 1000 (FIG. 10) are reused in the following discussion of FIG. 14.

By configuring the interconnect structure 1084 as the BL and the interconnect structure 1082 as the VSS, the epitaxial structure 1010A is electrically coupled to the VSS through the corresponding MD and via structure, the epitaxial structures 1010B-C are electrically coupled to the BL through the corresponding MD and via structure, the epitaxial structures 1010D-E are electrically coupled to the VSS through the corresponding MD and via structure, the epitaxial structures 1010F-G are electrically coupled to the BL through the corresponding MD and via structure, and the epitaxial structure 1010H-I is electrically coupled to the VSS through the corresponding MD and via structure, as illustrated in the hybrid cross-sectional view of FIG. 15. Accordingly, the first ROM cell 1440, the second ROM cell 1450, the third ROM cell 1430, and the fourth ROM cell 1460 can all present (or be programmed/coded with) a logical 1, in accordance with various embodiments of the present disclosure.

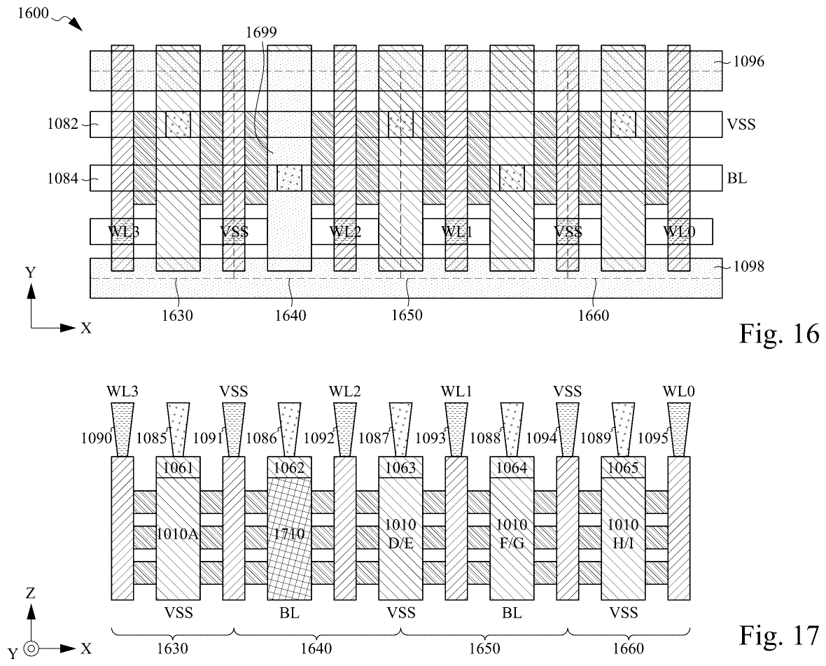

FIG. 16 illustrates an example layout 1600 configured to form (or program) a memory array including a first ROM cell (e.g., 1640), a second ROM cell (e.g., 1650), a third ROM cell (e.g., 1630), and a fourth ROM cell (e.g., 1660) that present a logical 0, a logical 1, a logical 1, and a logical 1, respectively, and FIG. 17 illustrates a hybrid cross-sectional view of the memory array formed by the layout 1600 (FIG. 16), in accordance with some embodiments. It should be understood that the layout of FIG. 16 and the corresponding memory array of FIG. 17 are provided merely for illustrative purposes, and are not intended to limit the scope of the present disclosure.

As shown in FIG. 16, the layout 1600 is substantially similar to the layout 1400 (FIG. 14), except that the layout 1600 further includes a pattern for forming another cut structure 1699 extending along a direction perpendicular to the cut structures 1096 and 1098. In some embodiments, the cut structure 1699, together with at least one of the cut structure 1096 or 1098, can sometimes be referred to as a cut structure having a T-shape. Accordingly, the reference numerals of other features similar in the layout 1400 (FIG. 14) are reused in the following discussion of FIG. 16.

In some embodiments, the cut structure 1699 can overlap the epitaxial structures 1010B and 1010C. As a result, after forming the epitaxial structures 1010B and 1010C (and other epitaxial structures in the active region 1010), the cut structure 1699 can be used to remove the epitaxial structures 1010B and 1010C to form a vertical trench that can expose respective sidewalls of the nanostructures that are respectively overlaid by the gate structures 1021 and 1022 and expose the major surface of the substrate, and the vertical trench can later be filled with a dielectric material to form a dielectric structure (e.g., 1710 shown in FIG. 17). The dielectric material of the dielectric structure 1710 can include silicon oxide, silicon nitride, or combinations thereof.

After filling up the vertical trench, the dielectric structure 1710 can be in physical contact with the exposed sidewalls of the nanostructures that are respectively overlaid by the gate structures 1021 and 1022, and in physical contact with the substrate. In some embodiments, the nanostructures overlaid by the gate structure 1022 operatively serve as the channel of the first ROM cell 1640. Next, the MDs 1061 to 1075 remain formed on top of the remaining epitaxial structures 1010A, the dielectric structure 1710, and the remaining epitaxial structures 1010D-H, respectively. As shown in FIG. 17, the MD 1062 is in physical contact with but electrically isolated from the dielectric structure 1710. Next, the via structures 1085 to 1095 can be evenly formed over the whole array, followed by the formation of the interconnect structures 1082, 1084, 1070, 1072, 1074, 1076, 1078, and 1080 that serve as the BL, VSS, WL3, VSS, WL2, WL1, VSS, and WL0, respectively.

Alternatively stated, the interconnect structure 1084 (BL) can be physically coupled to but electrically isolated from the dielectric structure 1710. The first ROM cell 1640 can have its source terminal electrically connected to the VSS and its drain terminal electrically disconnected from the BL, while each of the other ROM cells 1630, 1650, and 1660 can still have its drain and source terminals electrically connected to the BL and VSS, respectively. Accordingly, the first ROM cell 1640, the second ROM cell 1650, the third ROM cell 1630, and the fourth ROM cell 1660 can present (or be programmed/coded with) a logical 0, logical 1, logical 1, and a logical 1, respectively, in accordance with various embodiments of the present disclosure.

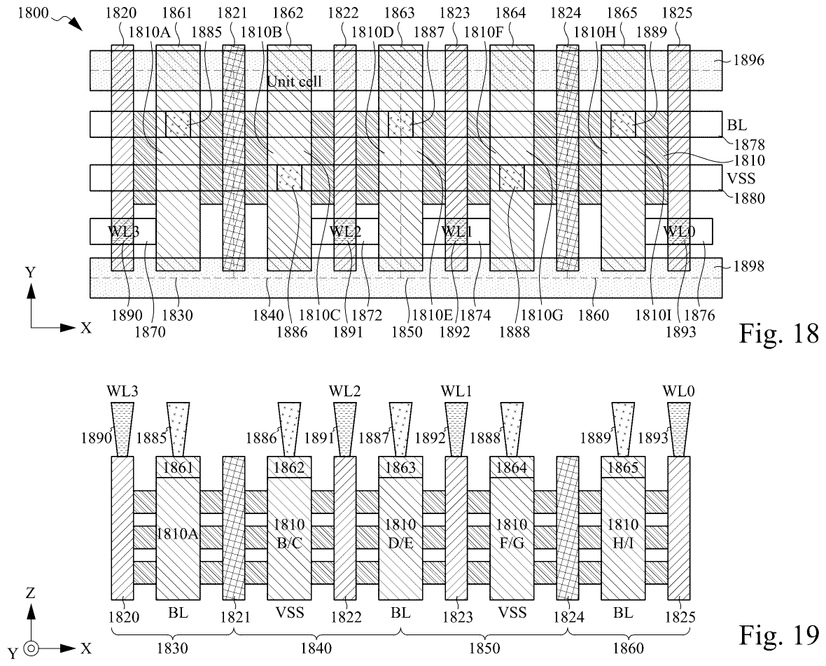

FIG. 18 illustrates an example layout 1800 configured to form (or program) a memory array including a first ROM cell, a second ROM cell, a third ROM cell, and a fourth ROM cell that all present a logical 1, and FIG. 19 illustrates a hybrid cross-sectional view of the memory array formed by the layout 1800 (FIG. 18), in accordance with some embodiments. It should be understood that the layout of FIG. 18 and the corresponding memory array of FIG. 19 are provided merely for illustrative purposes, and are not intended to limit the scope of the present disclosure.

Referring to FIG. 18, the layout 1800 includes patterns for forming an active region 1810, gate structures 1820, 1821, 1822, 1823, 1824, and 1825, respectively. It should be understood that the layout 1800 can include any number of other patterns to form respective active regions or gate structures, while remaining within the scope of present disclosure. In some embodiments, the active region 1810 can extend along a first lateral direction (e.g., the X-direction), and the gate structures 1820 to 1825 can each extend along a second lateral direction (e.g., the Y-direction) perpendicular to the first lateral direction. The gate structures 1820 to 1825 can each traverse the active region 1810. The gate structures 1820, 1822, 1823, and 1825 can each correspond to an active (e.g., metal) gate structure, while the gate structures 1821 and 1824 can each correspond to an inactive (e.g., dielectric) gate structure.

In some embodiments, the ROM cells of the memory array are each formed as a gate-all-around (GAA) transistor. However, the ROM cells of the memory array (formed by the layout 1800) can be formed as any of various other transistor structure while remaining within the scope of the present disclosure. In the example of GAA transistor structures, the active region 1810 can be formed of a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by each of the gate structure remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., straddles) the remaining portions of the semiconductor structures can be configured as a gate terminal of the transistor.

In FIG. 18, the active region 1810, together with the active gate structure 1822 and the inactive gate structure 1821, can form a first ROM cell 1840 with a one and half-transistor (1.5T) configuration. For example, the portion of the active region 1810 overlaid by the gate structure 1821 may include a number of first nanostructures vertically separated from each other, which can collectively function as the channel of a first sub-transistor, and the portion of the active region 1810 overlaid by the gate structure 1822 may include a number of second nanostructures vertically separated from each other, which can collectively function as the channel of a second sub-transistor. In some embodiments, the gate terminal (e.g., 1821) of the first sub-transistor is made of a dielectric material, causing the first sub-transistor to remain turned-off, while the gate terminal (e.g., 1822) of the second sub-transistor can be coupled to a corresponding word line (WL). Accordingly, the first ROM cell 1840 with a 1.5T configuration can be formed.

Further, the portions of the active region 1810 that are disposed on opposite sides of each of the gate structures 1821 and 1822 are replaced with epitaxial structures, respectively. Such epitaxial structures can function as source/drain terminals of the sub-transistors. For example, the gate structure 1822 can function as a gate terminal of the second sub-transistor, while the gate structure 1821, made of a dielectric material, can function as a gate terminal of the inactive (or turned-off) first sub-transistor. Epitaxial structures (1810D and 1810C) formed on the opposite sides of the gate structure 1822 can function as a first source/drain terminal and second source/drain terminal of the second sub-transistor, while epitaxial structure (1810B) formed on one side of the gate structure 1821 can function as one of the source/drain terminals of the inactive first sub-transistor. Similarly, the active region 1810, together with the active gate structure 1823 and inactive gate structure 1824, can form a second ROM cell 1850 in the same 1.5T configuration; the active region 1810, together with the active gate structure 1820 and the inactive gate structure 1821, can form a third ROM cell 1830 in the same 1.5T configuration; and the active region 1810, together with the active gate structure 1825 and the inactive gate structure 1824, can form a fourth ROM cell 1860 in the same 1.5T configuration.

Still referring to FIG. 18, the layout 1800 further includes patterns for forming source/drain contact structures (each sometimes referred to as MD) 1861, 1862, 1863, 1864, and 1865, interconnect structures 1870, 1872, 1874, 1876, 1878, and 1880, respectively. It should be understood that the layout 1800 can include any number of other patterns to form respective MDs or interconnect structures, while remaining within the scope of present disclosure. In some embodiments, the MDs 1861 to 1865 can each extend along the second lateral direction (e.g., the Y-direction), and the interconnect structures 1870 to 1880 can each extend along the first lateral direction (e.g., the X-direction). The MDs 1861 to 1865 can each be in electrical contact with a corresponding epitaxial structure (the source/drain terminal of a transistor or sub-transistor). The interconnect structures 1870 to 1880 can each be electrically coupled to one or more corresponding gate structures or one or more corresponding MDs.

For example, the interconnect structure 1872 coupled to the gate structure 1222 may serve as a first word line (WL2) of the memory array; the interconnect structure 1874 coupled to the gate structure 1823 may serve as a second word line (WL1) of the memory array; the interconnect structure 1870 coupled to the gate structure 1820 may serve as a third word line (WL3) of the memory array; the interconnect structure 1876 coupled to the gate structure 1625 may serve as a fourth word line (WL0) of the memory array; the interconnect structure 1880 coupled to the MDs 1862 and 1864 may serve as a power rail carrying the VSS (hereinafter “VSS”) for the memory array; and the interconnect structure 1878 coupled to the MDs 1861, 1863, and 1865 may serve as a bit line (BL) of the memory array.

The layout 1800 further includes patterns for forming a plural number of via structures 1885, 1886, 1887, 1888, 1889, 1890, 1891, 1892, and 1893, respectively. For example, the via structure 1885 can couple the MD 1861 (which is electrically coupled to one of the source/drain terminals of the ROM cell 1830) to the interconnect structure 1878 (BL); the via structure 1890 can couple the gate structure 1820 (which is the gate terminal of the ROM cell 1830) to the interconnect structure 1870 (WL3); the via structure 1886 can couple the MD 1862 (which is electrically coupled to one of the source/drain terminals of the ROM cell 1840) to the interconnect structure 180 (VSS); the via structure 1887 can couple the MD 1863 (which is electrically coupled to one of the source/drain terminals of the ROM cell 1840) to the interconnect structure 1878 (BL); and the via structure 1891 can couple the gate structure 1822 (which is the gate terminal of the ROM cell 1840) to the interconnect structure 1872 (WL2).

Based on the layout 1800 of FIG. 18, a memory array including at least a first ROM cell (e.g., 1840), a second ROM cell (e.g., 1850), a third ROM cell (e.g., 1830), and a fourth ROM cell (e.g., 1860) can be formed. For example, the first ROM cell 1840 includes its gate terminal, first source/drain terminal, and second source/drain terminal formed by the gate structure 1822, the epitaxial structure 1810D, and the epitaxial structure 1810C, respectively. Further, the first source/drain terminal of the first ROM cell 1840, which serve as a drain terminal of the first ROM cell 1840, and the second source/drain terminal of the first ROM cell 1840, which serve as a source terminal of the first ROM cell 1840, are electrically coupled to the interconnect structure 1878 that serves as the BL and the interconnect structure 1880 that serves as the VSS, respectively. The second ROM cell 1850 includes its gate terminal, first source/drain terminal, and second source/drain terminal formed by the gate structure 1823, the epitaxial structure 1810E, and the epitaxial structure 1810F, respectively. Further, the first source/drain terminal of the first ROM cell 1850, which serve as a drain terminal of the second ROM cell 1850, and the second source/drain terminal of the second ROM cell 1850, which serve as a source terminal of the second ROM cell 1850, are electrically coupled to the interconnect structure 1878 that serves as the BL and the interconnect structure 1880 that serves as the VSS, respectively.

The hybrid cross-sectional view of FIG. 19 illustrates a combination of cross-sectional views of the memory array formed based on the layout 1900 (FIG. 19). For example, a first cross-sectional view can be cut along the interconnect structure 1878 (BL), which shows at least the epitaxial structures 1810A to 1810I, the MDs 1861 to 1865 disposed thereupon, and the via structures 1885, 1887, and 1889; a second cross-sectional view can be cut along the interconnect structure 1880 (VSS), which shows at least the epitaxial structures 1810A to 1810I, the MDs 1861 to 1865 disposed thereupon, and the via structures 1886 and 1888; and a third cross-sectional view can be cut along the interconnect structures 1870 to 1876 (WL3, WL2, WL1, WL0), which shows the gate structures 1820 to 1825, the via structures 1890 to 1893 disposed thereupon, and the MDs 1861 to 1865.

As shown in FIG. 19, the first ROM cell 1840 can have its source terminal (formed by the merged epitaxial structures 1810B and 1810C) electrically coupled to the VSS through the MD 1862 and via structure 1886, its drain terminal (formed by the merged epitaxial structures 1810D and 1810E) electrically coupled to the BL through the MD 1863 and via structure 1887, and its gate terminal (formed by the gate structure 1822) electrically coupled to the WL2 through the via structure 1892. The second ROM cell 1850 can have its source terminal (formed by the merged epitaxial structures 1810F and 1810G) electrically coupled to the VSS through the MID 1864 and via structure 1888, its drain terminal (formed by the merged epitaxial structures 1810D and 1810E) electrically coupled to the BL through the MD 1863 and via structure 1887, and its gate terminal (formed by the gate structure 1823) electrically coupled to the WL1 through the via structure 1892. The third ROM cell 1830 and the fourth ROM cell 1860 can have their respective gate terminals, drain terminals, and source terminals with similar electrical connection, and thus, the description is not repeated. Accordingly, the ROM cell 1830 to 1860 can all present (or be programmed/coded with) a logical 1, in accordance with various embodiments of the present disclosure.

Referring again to FIG. 18, the layout 1800 can further include patterns for forming a first cut structure 1896 and a second cut structure 1898, respectively. As shown, the cut structures 1896 and 1898 are in parallel with each other and extend along the first lateral direction (e.g., the X-direction). In some embodiments, the cut structures 1896 and 1898 can each traverse across the gate structures 1820 to 1825 to separate each of the gate structures 1820 to 1825 into multiple sections (separated apart from one another along the Y-direction). For example, the cut structure 1896 can separate each of the gate structures 1820 to 1825 shown in FIG. 18 from its respective section disposed above the ROM cells 1830-1860 along the Y-direction (not shown); and the cut structure 1898 can separate each of the gate structures 1820 to 1825 shown in FIG. 18 from its respective section disposed below the ROM cells 1830-1860 along the Y-direction (not shown).

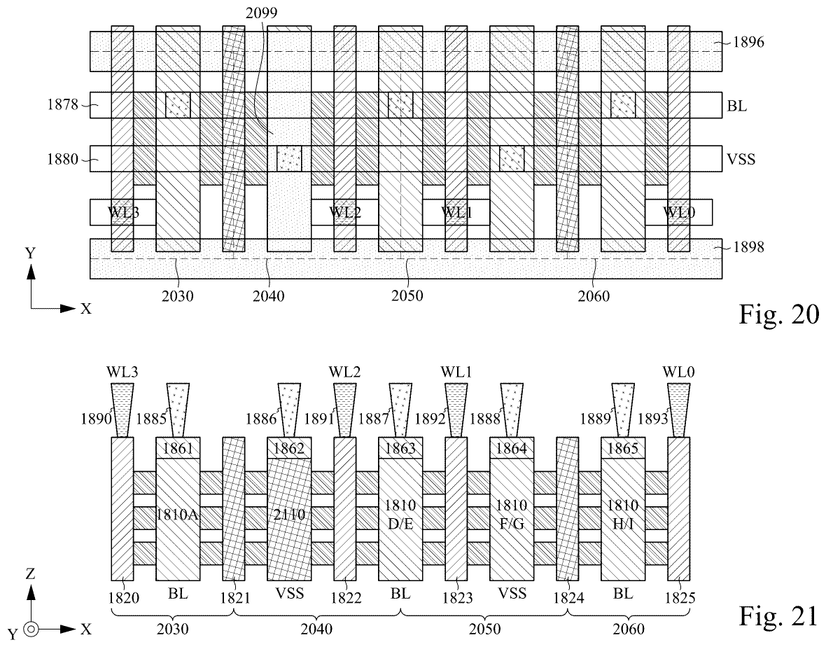

FIG. 20 illustrates an example layout 2000 configured to form (or program) a memory array including a first ROM cell (e.g., 2040), a second ROM cell (e.g., 2050), a third ROM cell (e.g., 2030), and a fourth ROM cell (e.g., 2060) that present a logical 0, a logical 1, a logical 1, and a logical 1, respectively, and FIG. 21 illustrates a hybrid cross-sectional view of the memory array formed by the layout 2000 (FIG. 20), in accordance with some embodiments. It should be understood that the layout of FIG. 20 and the corresponding memory array of FIG. 21 are provided merely for illustrative purposes, and are not intended to limit the scope of the present disclosure.

The layout 2000 is substantially similar to the layout 1800 (FIG. 18), except that the layout 2000 further includes a pattern for forming another cut structure 2099 extending along a direction perpendicular to the cut structures 1896 and 1898. In some embodiments, the cut structure 2099, together with at least one of the cut structure 1896 or 1898, can sometimes be referred to as a cut structure having a T-shape. Accordingly, the reference numerals of other features similar in the layout 1800 (FIG. 18) are reused in the following discussion of FIG. 20.

In some embodiments of the present disclosure, the cut structure 2099 can overlap the epitaxial structures 1810B and 1810C. As a result, after forming the epitaxial structures 1810B and 1810C (and other epitaxial structures in the active region 1810), the cut structure 2099 can be used to remove the epitaxial structures 1810B and 1810C to form a vertical trench that can expose respective sidewalls of the nanostructures that are respectively overlaid by the gate structures 1821 and 1822 and expose the major surface of the substrate, and the vertical trench can later be filled with a dielectric material to form a dielectric structure (e.g., 2110 shown in FIG. 121). The dielectric material of the dielectric structure 2110 can include silicon oxide, silicon nitride, or combinations thereof.

After filling up the vertical trench, the dielectric structure 2110 can be in physical contact with the exposed sidewalls of the nanostructures that are respectively overlaid by the gate structures 1821 and 1822, and in physical contact with the substrate. In some embodiments, the nanostructures overlaid by the gate structure 1821 operatively serve as the channel of the inactive first sub-transistor of the first ROM cell 2040, and the nanostructures overlaid by the gate structure 1822 operatively serve as the channel of the second sub-transistor of the first ROM cell 2040. Next, the MDs 1861 to 1865 remain formed on top of the remaining epitaxial structures 1810A, the dielectric structure 2110, and 1810D-I, respectively. As shown in FIG. 21, the MD 1862 is in physical contact with but electrically isolated from the dielectric structure 2110. Next, the via structures 1885 to 1893 can be evenly formed over the whole array, followed by the formation of the interconnect structures 1878, 1880, 1870, 1872, 1874, and 1876 that serve as the BL, VSS, WL3, WL2, WL1, and WL0, respectively.

Alternatively stated, the interconnect structure 1880 (VSS) can be physically coupled to but electrically isolated from the dielectric structure 2110. The first ROM cell 2040 can have its drain terminal electrically connected to the BL and its source terminal electrically disconnected from VSS, while each of the other ROM cells 2030, 2050, and 2060 can still have its drain and source terminals electrically connected to the BL and VSS, respectively. Accordingly, the first ROM cell 2040, the second ROM cell 2050, the third ROM cell 2030, and the fourth ROM cell 2060 can present (or be programmed/coded with) a logical 0, a logical 1, a logical 1, and a logical 1, respectively, in accordance with various embodiments of the present disclosure.

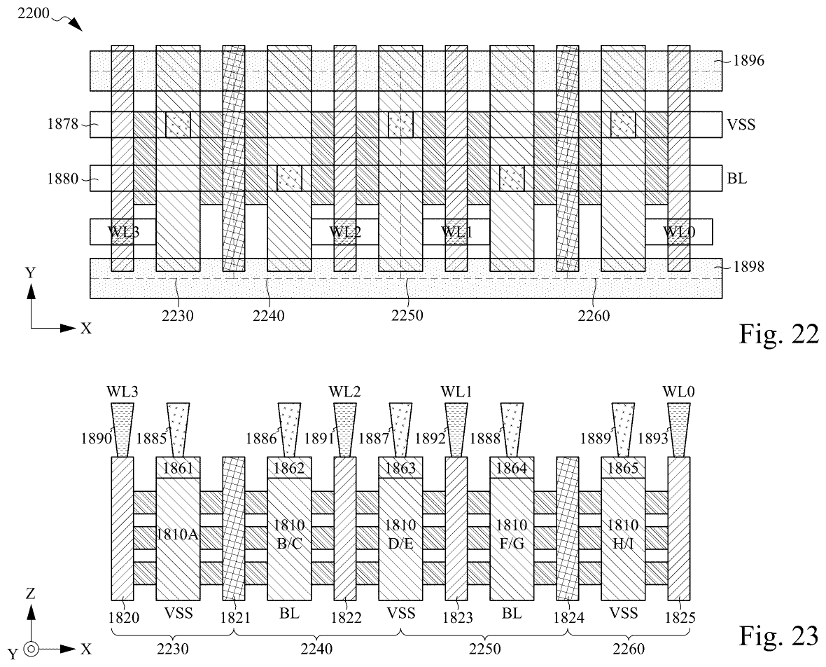

FIG. 22 illustrates an example layout 2200 configured to form (or program) a memory array including a first ROM cell (e.g., 2240), a second ROM cell (e.g., 2250), a third ROM cell (e.g., 2230), and a fourth ROM cell (e.g., 2260) that all present a logical 1, and FIG. 23 illustrates a hybrid cross-sectional view of the memory array formed by the layout 2200 (FIG. 22), in accordance with some embodiments. It should be understood that the layout of FIG. 22 and the corresponding memory array of FIG. 23 are provided merely for illustrative purposes, and are not intended to limit the scope of the present disclosure.

As shown, the layout 2200 is substantially similar to the layout 1800 (FIG. 18), except that interconnect structures 1878 and 1880 of the layout 2200 are configured as the VSS and BL, respectively. Accordingly, the reference numerals of other features similar in the layout 1800 (FIG. 18) are reused in the following discussion of FIG. 22.

By configuring the interconnect structure 1880 as the BL and the interconnect structure 1878 as the VSS, the epitaxial structure 1810A is electrically coupled to the VSS through the corresponding MD and via structure, the epitaxial structures 1810B-C are electrically coupled to the BL through the corresponding MD and via structure, the epitaxial structures 1810D-E are electrically coupled to the VSS through the corresponding MD and via structure, the epitaxial structures 1810F-G are electrically coupled to the BL through the corresponding MD and via structure, and the epitaxial structure 1810H-I is electrically coupled to the VSS through the corresponding MD and via structure, as illustrated in the hybrid cross-sectional view of FIG. 23. Accordingly, the first ROM cell 2240, the second ROM cell 2250, the third ROM cell 2230, and the fourth ROM cell 2260 can all present (or be programmed/coded with) a logical 1, in accordance with various embodiments of the present disclosure.

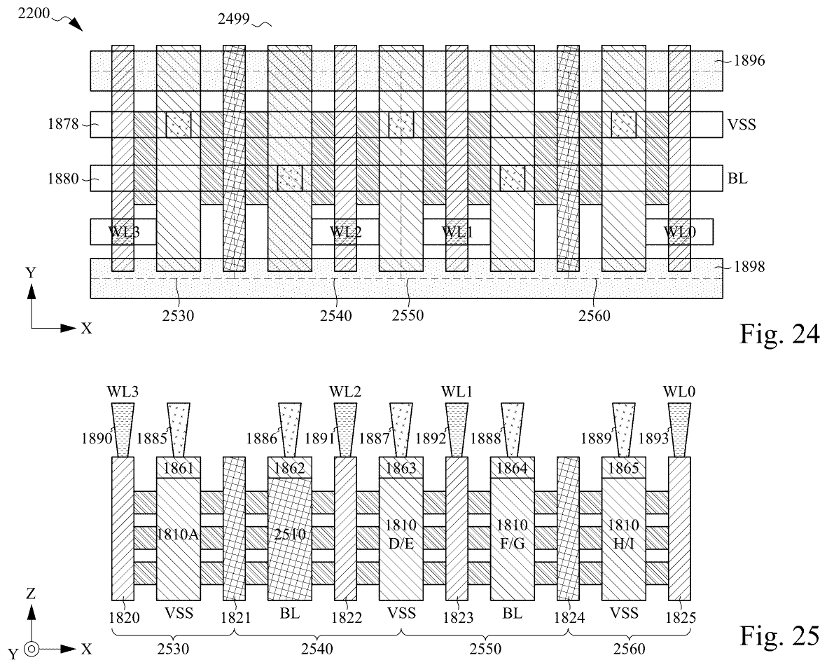

FIG. 24 illustrates an example layout 2400 configured to form (or program) a memory array including a first ROM cell (e.g., 2440), a second ROM cell (e.g., 2450), a third ROM cell (e.g., 2430), and a fourth ROM cell (e.g., 2460) that present a logical 0, a logical 1, a logical 1, and a logical 1, respectively, and FIG. 25 illustrates a hybrid cross-sectional view of the memory array formed by the layout 2400 (FIG. 24), in accordance with some embodiments. It should be understood that the layout of FIG. 24 and the corresponding memory array of FIG. 25 are provided merely for illustrative purposes, and are not intended to limit the scope of the present disclosure.

As shown in FIG. 24, the layout 2400 is substantially similar to the layout 2200 (FIG. 22), except that the layout 2400 further includes a pattern for forming another cut structure 2499 extending along a direction perpendicular to the cut structures 1896 and 1898. In some embodiments, the cut structure 2499, together with at least one of the cut structure 1896 or 1898, can sometimes be referred to as a cut structure having a T-shape. Accordingly, the reference numerals of other features similar in the layout 2200 (FIG. 22) are reused in the following discussion of FIG. 24.

In some embodiments, the cut structure 2499 can overlap the epitaxial structures 1810B and 1810C. As a result, after forming the epitaxial structures 1810B and 1810C (and other epitaxial structures in the active region 1810), the cut structure 2499 can be used to remove the epitaxial structures 1810B and 1810C to form a vertical trench that can expose respective sidewalls of the nanostructures that are respectively overlaid by the gate structures 1821 and 1822 and expose the major surface of the substrate, and the vertical trench can later be filled with a dielectric material to form a dielectric structure (e.g., 2510 shown in FIG. 25). The dielectric material of the dielectric structure 2510 can include silicon oxide, silicon nitride, or combinations thereof.

After filling up the vertical trench, the dielectric structure 2510 can be in physical contact with the exposed sidewalls of the nanostructures that are respectively overlaid by the gate structures 1821 and 1822, and in physical contact with the substrate. In some embodiments, the nanostructures overlaid by the gate structure 1822 operatively serve as the channel of the first ROM cell 2540. Next, the MDs 1861 to 1875 remain formed on top of the remaining epitaxial structures 1810A, the dielectric structure 2510, and the remaining epitaxial structures 1810D-H, respectively. As shown in FIG. 25, the MD 1862 is in physical contact with but electrically isolated from the dielectric structure 2510. Next, the via structures 1885 to 1893 can be evenly formed over the whole array, followed by the formation of the interconnect structures 1878, 1880, 1870, 1872, 1874, and 1876 that serve as the VSS, BL, WL3, WL2, WL1, and WL0, respectively.

Alternatively stated, the interconnect structure 1880 (BL) can be physically coupled to but electrically isolated from the dielectric structure 2510. The first ROM cell 2540 can have its source terminal electrically connected to the VSS and its drain terminal electrically disconnected from the BL, while each of the other ROM cells 2530, 2550, and 2560 can still have its drain and source terminals electrically connected to the BL and VSS, respectively. Accordingly, the first ROM cell 2540, the second ROM cell 2550, the third ROM cell 2530, and the fourth ROM cell 2560 can present (or be programmed/coded with) a logical 0, logical 1, logical 1, and a logical 1, respectively, in accordance with various embodiments of the present disclosure.

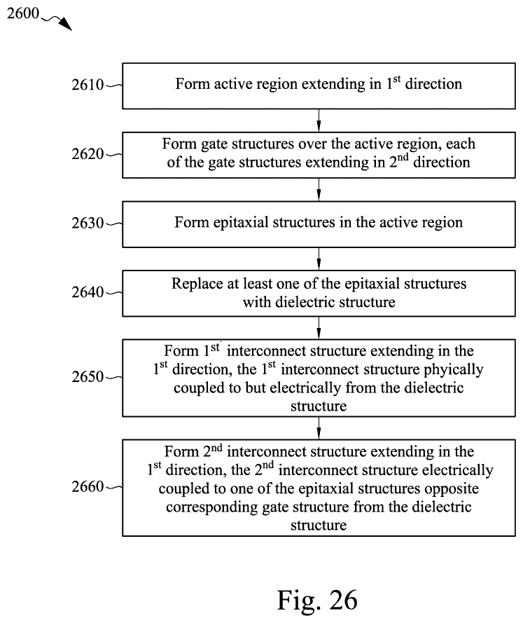

FIG. 26 illustrates a flow chart of an example method 2600 for forming a memory device (e.g., a memory array), in accordance with various embodiments of the present disclosure. In some embodiments, the memory device can be formed based on the layout 400 (FIGS. 4), 800 (FIGS. 8), 1200 (FIGS. 12), 1600 (FIGS. 16), 2000 (FIG. 20), or 2400 (FIG. 24), so as to have at least one of its memory cells programmed with a logic state different from other memory cells. Accordingly, the following discussion of the method 2600 may refer to some of the above figures. It should be noted that the method 2600 as shown in FIG. 26 is merely an example, and is not intended to limit the present disclosure. Thus, it is understood that the order of the operations of the method 2600 of FIG. 26 can be changed, for example, additional operations may be provided before, during, and after the method 2600, and that some operations may only be described briefly herein.

The method 2600 starts with operation 2610 of forming an active region extending along a first lateral direction. Using the layout 400 (FIG. 4) as a representative example, the active region 210, extending the X-direction, can be formed over a semiconductor substrate. In an example, the active region 210 can be formed as a stack of first semiconductor layers (e.g., SiGe) and second semiconductor layers (e.g., Si) alternately staked on top of one another, where the first semiconductor layers may later be replaced as one or more gate structures and the semiconductor layers may be configured as channels of one or more GAA transistors.

The method 2600 continues to operation 2620 of forming a plurality of gate structures over the active region, each of the gate structures extending along a second lateral direction perpendicular to the first lateral direction. Continuing with the above example, the gate structures can be 220 to 225, extending in the Y-direction, can be formed over the active region 210. Each of the gate structures can be 220 to 225 can traverse the active region 210. In an example, the gate structures 220 to 225 may be first formed as dummy gate structures and later be replaced with metal gate structures, respectively.

The method 2600 continues to operation 2630 of forming a plurality of epitaxial structures in the active region, each of the gate structures interposed between adjacent ones of the epitaxial structures. In some embodiments, the active region, the gate structures, and the epitaxial structure operatively form a plurality of memory cells. Still with the same example of FIG. 4, after forming the (e.g. dummy) gate structures 220 to 225, portions of the active region 210 that are not overlaid by the gate structures 220 to 225 are replaced with the epitaxial structures 210A to 210H. In the example layout of FIG. 4 where each memory cell is formed in a 2T configuration, each memory cell (e.g., 430, 440) may be formed as two sub-transistors coupled in parallel, one of which is formed by a first one of the gate structures (e.g., 221) and the epitaxial structures (e.g., 210A and 210B) disposed on its opposite sides and the other of which is formed by a second one of the gate structures (e.g., 222) and the epitaxial structures (e.g., 210C and 210D) disposed on its opposite sides.

The method 2600 continues to operation 2640 of replacing at least one of the epitaxial structures with a dielectric structure. In the same example of FIG. 4, in order to program the memory cell 430, the epitaxial structure 210B/C is replaced with the dielectric structure 510. In some embodiments, the dielectric structure 510 may be formed by at least some of the process steps: exposing the epitaxial structure 210B/C while masking other epitaxial structures; performing one or more etching processes to remove the epitaxial structure 210B/C (thereby forming a vertical trench or recess); filling the trench with a dielectric material; and performing a polishing process.

The method 2600 continues to operation 2650 of forming a first interconnect structure extending along the first lateral direction, the first interconnect structure being physically coupled to but electrically isolated from the dielectric structure. After forming the dielectric structure 510, the first interconnect structure 270, extending in the X-direction, can be formed. In one embodiment, the first interconnect structure 270 can be configured as a power rail carrying VSS for the memory device (FIGS. 4-5). In another embodiment, the first interconnect structure 270 can be configured as a bit line (BL) for the memory device (FIGS. 8-9). The first interconnect structure 270 is physically coupled to but electrically isolated from the dielectric structure 510, which replaces one of the source/drain terminals of the memory cell 430, allowing the memory cell 430 to be disconnected from the VSS (FIGS. 4-5) or from the BL (FIGS. 8-9).

The method 2600 continues to operation 2660 of forming a second interconnect structure also extending along the first lateral direction, the second interconnect structure electrically coupled to one of the epitaxial structures opposite a corresponding one of the gate structure from the dielectric structure. Concurrently with forming the first interconnect structure 270, the second interconnect structure 275, extending in the X-direction, can be formed. In one embodiment, the second interconnect structure 275 can be configured as the BL for the memory device (FIGS. 4-5). In another embodiment, the second interconnect structure 275 can be configured as the VSS for the memory device (FIGS. 8-9). In some embodiments, the second interconnect structure 275 is electrically coupled to an epitaxial structure (e.g., 210A, 210D) opposite a corresponding one of the gate structures (e.g., 221, 222) from the dielectric structure 510.

In one aspect of the present disclosure, a memory device is disclosed. The memory device includes a plurality of memory cells, each of the plurality of memory cells configured to store a data bit; a first interconnect structure operatively configured as a bit line and coupled to each of the plurality of memory cells; and a second interconnect structure operatively configured to carry a supply voltage and coupled to each of the plurality of memory cells. The data bit stored by a first one of the plurality of memory cells presents a first logic state when the first memory cell includes a first channel structure, with a first end of the first channel structure connected to a dielectric structure.

In another aspect of the present disclosure, a memory device is disclosed. The memory device includes a plurality of memory cells being formed over an active region that extends along a lateral direction; a first interconnect structure operatively configured as a bit line and extending along the same lateral direction; a second interconnect structure operatively configured as a power rail carrying a ground voltage and extending along the same lateral direction; a plurality of epitaxial structures formed in the active region; and one or more dielectric structures formed in the active region.

In yet another aspect of the present disclosure, a method for fabricating memory devices is disclosed. The method includes forming an active region extending along a first lateral direction. The method includes forming a plurality of gate structures over the active region, each of the gate structures extending along a second lateral direction perpendicular to the first lateral direction. The method includes forming a plurality of epitaxial structures in the active region, each of the gate structures interposed between adjacent ones of the epitaxial structures, wherein the active region, the gate structures, and the epitaxial structure operatively form a plurality of memory cells. The method includes replacing at least one of the epitaxial structures with a dielectric structure. The method includes forming a first interconnect structure extending along the first lateral direction, the first interconnect structure being physically coupled to but electrically isolated from the dielectric structure. The method includes forming a second interconnect structure also extending along the first lateral direction, the second interconnect structure electrically coupled to one of the epitaxial structures opposite a corresponding one of the gate structure from the dielectric structure.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a plurality of memory cells, each of the plurality of memory cells configured to store a data bit;
a first interconnect structure operatively configured as a bit line and coupled to each of the plurality of memory cells; and
a second interconnect structure operatively configured to carry a supply voltage and coupled to each of the plurality of memory cells;
wherein the data bit stored by a first one of the plurality of memory cells presents a first logic state when the first memory cell includes a first channel structure, with a first end of the first channel structure connected to a dielectric structure.

2. The memory device of claim 1, wherein each of the plurality of memory cells is a read only memory (ROM) cell.

3. The memory device of claim 1, wherein the supply voltage is a ground voltage.

4. The memory device of claim 1, wherein the dielectric structure is physically coupled to the first interconnect structure.

5. The memory device of claim 4, wherein the first channel structure of the first memory cell has a second end connected to an epitaxial structure electrically coupled to the second interconnect structure.

6. The memory device of claim 1, wherein the dielectric structure is physically coupled to but electrically isolated from the second interconnect structure.

7. The memory device of claim 6, wherein the first channel structure of the first memory cell has a second end connected to an epitaxial structure electrically coupled to the second interconnect structure.

8. The memory device of claim 1, wherein the data bit stored by a second one of the plurality of memory cells presents a second logic state when the second memory cell includes a second channel structure, with a first end and a second end of the second channel structure connected to a first epitaxial structure and a second epitaxial structure, respectively.

9. The memory device of claim 8, wherein the first epitaxial structure is electrically coupled to the first interconnect structure, and the second epitaxial structure is electrically coupled to the second interconnect structure.

10. The memory device of claim 8, wherein the second memory cell is disposed next the first memory cell along a lateral direction, and each of the first and second interconnect structures extends along the same lateral direction.

11. The memory device of claim 1, wherein the dielectric structure vertically extends to be in contact with a substrate where the memory cells are formed.

12. A memory device, comprising:
a plurality of memory cells being formed over an active region that extends along a lateral direction;
a first interconnect structure operatively configured as a bit line and extending along the same lateral direction;
a second interconnect structure operatively configured as a power rail carrying a ground voltage and extending along the same lateral direction;
a plurality of epitaxial structures formed in the active region; and
one or more dielectric structures formed in the active region.

13. The memory device of claim 12, wherein each of the plurality of memory cells is a read only memory (ROM) cell.

14. The memory device of claim 12, wherein at least a first one of the plurality of memory cells has its channel structure formed in the active region and connected to at least one of the one or more dielectric structures.

15. The memory device of claim 14, wherein the at least one dielectric structure is physically coupled to but electrically isolated from one of the first interconnect structure or second interconnect structure.

16. The memory device of claim 12, wherein at least a second one of the plurality of memory cells has its channel structure formed in the active region, and connected to a first one of the epitaxial structures and a second one of the epitaxial structures.

17. The memory device of claim 16, wherein the first epitaxial structure and the second epitaxial structure are electrically coupled to the first interconnect structure and the second interconnect structure, respectively.

18. A method for forming a memory device, comprising:
forming an active region extending along a first lateral direction;
forming a plurality of gate structures over the active region, each of the gate structures extending along a second lateral direction perpendicular to the first lateral direction;
forming a plurality of epitaxial structures in the active region, each of the gate structures interposed between adjacent ones of the epitaxial structures, wherein the active region, the gate structures, and the epitaxial structure operatively form a plurality of memory cells;
replacing at least one of the epitaxial structures with a dielectric structure;
forming a first interconnect structure extending along the first lateral direction, the first interconnect structure being physically coupled to but electrically isolated from the dielectric structure; and
forming a second interconnect structure also extending along the first lateral direction, the second interconnect structure electrically coupled to one of the epitaxial structures opposite a corresponding one of the gate structure from the dielectric structure.

19. The method of claim 18, wherein the first interconnect structure is configured as a bit line for the plurality of memory cells, and the second interconnect structure is configured for carrying a ground voltage for the plurality of memory cells.

20. The method of claim 18, wherein the second interconnect structure is configured as a bit line for the plurality of memory cells, and the first interconnect structure is configured for carrying a ground voltage for the plurality of memory cells.
